(19) United States
(12) Patent Application Publication
(10) Pub. No.: US 2007/0224856 A1
(43) Pub. Date: Sep. 27, 2007

(54) Positioning method and board

(75) Inventors: Satoshi Torii, Echizen-city (JP); Hisataka Yoshimura, Echizen-city (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: ORION ELECTRIC CO., LTD., Echizen-city (JP)

(21) Appl. No.: 11/714,165

(22) Filed: Mar. 6, 2007

(30) Foreign Application Priority Data
Mar. 27, 2006 (JP) 2006-085234

(51) Int. Cl. H05K 1/00

(52) U.S. Cl. 439/83

(57) ABSTRACT

Disclosed are a positioning method and a board for swiftly and accurately adjusting the position of a warpage-preventive rail for preventing warpage of the board in flow soldering. A mark of a width B provided with a slit having a width A in a direction perpendicular to a dip direction indicated by an arrow is silk-screen printed at an end of a surface opposite to a flow solder surface of a board. The width B of the mark is set to such a value that an operator who adjusts the position can easily recognize the mark. The slit is formed on a surface opposite to a support band where the upper surface of the warpage-preventive rail supports the board, and the width A of the slit is set to a value approximately equal to the width of the upper surface of the warpage-preventive rail.

The present application is based on and claims priority of Japanese patent application No. 2006-085234 filed on Mar. 27, 2006, the entire contents of which are hereby incorporated by reference.

### BACKGROUND OF THE INVENTION

1. Field of the Invention

The present invention relates to a positioning method for adjusting the position of a warpage-preventive rail for supporting a board from below to prevent downward warpage of the board when components are flow-soldered onto the board in a molten solder bath and to the board that is supported from below by the warpage-preventive rail. More particularly, the invention relates to the positioning method for swiftly and accurately adjusting the position of a warpage-preventive rail and to the board for swiftly and accurately adjusting the position of the warpage-preventive rail.

2. Description of the Related Art

Methods for soldering components onto a board include flow soldering. According to the flow soldering, components are glued on a board, and the board is soldered by being passed through a molten solder bath, with a solder surface downward.

However, in the flow soldering, when the board is passed through the molten solder bath, approximately the center portion of the board is warped downward by heat. This warpage disables jet solder from contacting the board uniformly, thereby sometimes causing poor soldering.

Japanese Patent Application Laid-Open Nos. 6-302943 and 5-92258 (Patent documents 1 and 2) disclose techniques for preventing downward warpage of approximately the center portion of a board by providing a board supporting rail (warpage-preventive rail) between board conveying rails. FIG. 9 is a perspective view showing an example of a warpage-preventive rail, and FIG. 10 is a longitudinal sectional view of the warpage-preventive rail. An upper surface 62 of the warpage-preventive rail 61 contacts and supports the board. A solder surface of the board needs to be constructed such that it can be passed through a molten solder bath with the surface being supported by the warpage-preventive rail. That is, the board needs to be designed such that the warpage-preventive rail does not contact components or lands.

FIG. 11 is a bottom view showing a solder surface (facing downward in passing through a molten solder bath) of a board 91 that can be supported by the warpage-preventive rail shown in FIGS. 9 and 10. An arrow 71 indicates a dip direction. A support band 51 is an area which the warpage-preventive rail contacts on the solder surface of the board 91. That is, the upper surface of the warpage-preventive rail supports the support band 51, thereby preventing downward warpage of the board 91.

The support band 51 has a width equal to the width (1 mm in the case of the example of the warpage-preventive rail shown in FIGS. 10 and 11), perpendicular to a dip direction, of the board supporting surface (i.e., the upper surface) of the warpage-preventive rail. Since the support band 51 is directly contacted by the warpage-preventive rail, components and lands cannot be placed in the support band 51. Further, since there is a high possibility that a solder jet is disturbed in the vicinity of the support band 51 so that poor soldering occurs, components cannot be placed in this area (a forbidden band 52) either. That is, the board needs to be designed such that components and lands are not placed in the support band 51 and the forbidden band 52 (a width of 4 mm in FIG. 11).

If the type of a board to be flow-soldered changes, the position of the support band 51 and the forbidden band 52 also changes. Therefore, every time the type of a board to be flow-soldered changes, the position of the warpage-preventive rail needs to be adjusted. If the position of the warpage-preventive rail is adjusted after a soldering apparatus is turned off and the molten solder bath is cooled, a soldering operation is stopped for many hours for cooling, which reduces operation efficiency. For this reason, the position of the warpage-preventive rail is adjusted under a high temperature condition where the soldering apparatus is not turned off.

The temperature of the molten solder bath is maintained at a high temperature (e.g., 250 degrees centigrade), so that the inside of the soldering apparatus is also brought to a high temperature. An operator puts his or her upper body in this small high-temperature soldering apparatus to adjust the position of the warpage-preventive rail. However, the operator cannot put the upper body in the soldering apparatus for more than about 30 to 45 seconds; therefore, the positioning of the warpage-preventive rail needs to be performed within a short time. For this reason, a mark is formed on a surface (facing upward in flow soldering) opposite to the solder surface of the board, and the operator adjusts the position of the warpage-preventive rail with the mark as a guide.

FIG. 12 is a top view illustrating the positions of the board 91 having the mark 92 and the warpage-preventive rail 61. In general, various kinds of board information are printed on the board. For swift operation in the soldering apparatus, the mark for adjusting the position of the warpage-preventive rail needs to be such a size (e.g., a width of 4 mm) that it can be easily recognized among the various kinds of board information.

### SUMMARY OF THE INVENTION

The mark for adjusting the position of the warpage-preventive rail is formed in such a size (e.g., a width of 4 mm) that it can be easily recognized. In general, the width (e.g., 1 mm) of the upper surface of the warpage-preventive rail is smaller than the width of the mark. For this reason, the positioning of the warpage-preventive rail is performed such that the upper surface of the warpage-preventive rail is positioned in the center of the mark, thus causing a troublesome operation and poor positioning accuracy. Further, in the case of poor positioning accuracy of the warpage-preventive rail, there is a problem that a solder jet is disturbed in the vicinity of the forbidden band so that poor soldering occurs easily.

The present invention has been made in view of the above circumstance, and it is an object of the invention to provide a positioning method for swiftly and accurately adjusting the position of a warpage-preventive rail for preventing warpage of a board in flow soldering and provide a board for swiftly and accurately adjusting the position of the warpage-preventive rail.

A first aspect of the invention relates to a positioning method of a warpage-preventive rail for supporting a board from below to prevent downward warpage of the board when a component is flow-soldered onto the board in a molten solder bath. The positioning method includes the steps of forming a mark provided with a slit having a width approximately equal to a width, perpendicular to a dip direction, of a surface of the warpage-preventive rail facing the board, at an end of a surface opposite to a flow solder surface of the board; and adjusting a position of the warpage-preventive rail to the slit.

According to the positioning method of the first aspect, it is possible to easily recognize the mark and form on the board the slit approximately equal to the width of the warpage-preventive rail.

A second aspect of the invention relates to a positioning method of a warpage-preventive rail for supporting a board from below to prevent downward warpage of the board when a component is flow-soldered onto the board in a molten solder bath. The positioning method includes the steps of forming a notch having a width approximately equal to a width, perpendicular to a dip direction, of a surface of the warpage-preventive rail facing the board, at an end of a surface opposite to a flow solder surface of the board; forming a mark around the notch; and adjusting a position of the warpage-preventive rail to the notch.

According to the positioning method of the second aspect, it is possible to easily recognize the mark and form on the board the notch approximately equal to the width of the warpage-preventive rail.

A third aspect of the invention relates to the positioning method of the first or second aspect, wherein the mark is formed by silk-screen printing.

According to the positioning method of the third aspect, it is possible to form the mark by silk-screen printing.

A fourth aspect of the invention relates to a board that is supported from below by a warpage-preventive rail for preventing downward warpage of the board when a component is flow-soldered onto the board in a molten solder bath. The board includes a mark provided with a slit having a width approximately equal to a width, perpendicular to a dip direction, of a surface of the warpage-preventive rail facing the board, at an end of a surface opposite to a flow solder surface of the board.

According to the board of the fourth aspect, it is possible to easily recognize the mark and form on the board the slit approximately equal to the width of the warpage-preventive rail.

A fifth aspect of the invention relates to a board that is supported from below by a warpage-preventive rail for preventing downward warpage of the board when a component is flow-soldered onto the board in a molten solder bath. The board includes a notch having a width approximately equal to a width, perpendicular to a dip direction, of a surface of the warpage-preventive rail facing the board, at an end of a surface opposite to a flow solder surface of the board; and a mark formed around the notch.

According to the board of the fifth aspect, it is possible to easily recognize the mark and form on the board the notch approximately equal to the width of the warpage-preventive rail.

A sixth aspect of the invention relates to the board of the fourth or fifth aspect, wherein the mark is formed by silk-screen printing.

According to the board of the sixth aspect, it is possible to form the mark by silk-screen printing.

### BRIEF DESCRIPTION OF THE DRAWINGS

In the accompanying drawings,

FIG. 1 is an illustration showing a board according to a first embodiment of the present invention;

FIG. 2 is a top view illustrating the positions of the board according to the first embodiment of the invention and a warpage-preventive rail;

FIG. 3 is a perspective view illustrating the positions of the board according to the first embodiment of the invention and the warpage-preventive rail;

FIG. 4 is an illustration showing a board according to a second embodiment of the invention;

FIG. 5 is a top view illustrating the positions of the board according to the second embodiment of the invention and the warpage-preventive rail;

FIG. 6 is a perspective view illustrating the positions of the board according to the second embodiment of the invention and the warpage-preventive rail;

FIG. 7 is a top view illustrating the positions of the board according to the second embodiment of the invention and the warpage-preventive rail;

FIG. 8 is a perspective view illustrating the positions of the board according to the second embodiment of the invention and the warpage-preventive rail;

FIG. 9 is a perspective view showing the warpage-preventive rail;

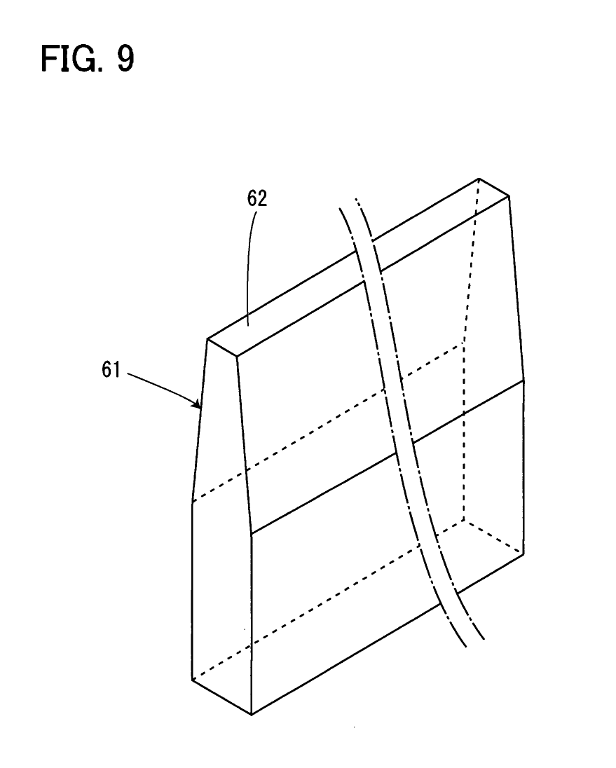

FIG. 10 is a longitudinal sectional view of the warpage-preventive rail;

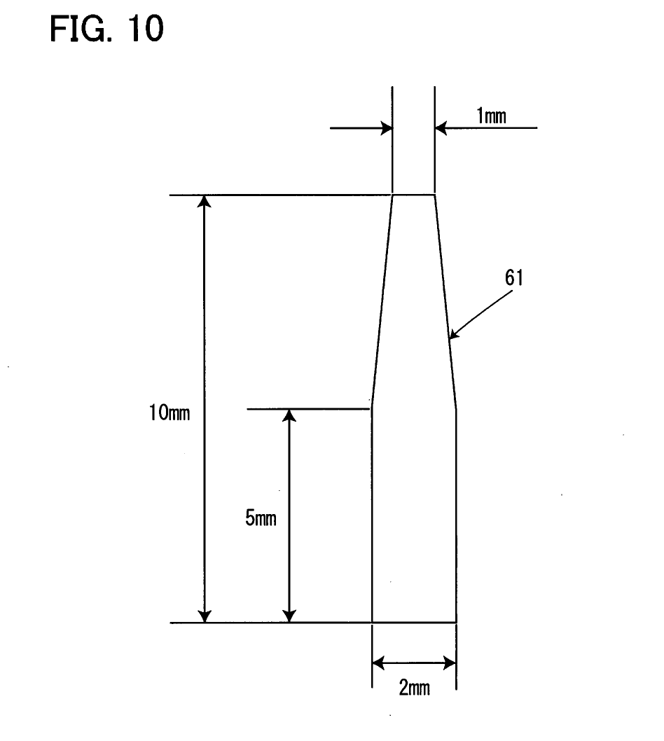

FIG. 11 is a bottom view showing a board according to a conventional technique; and

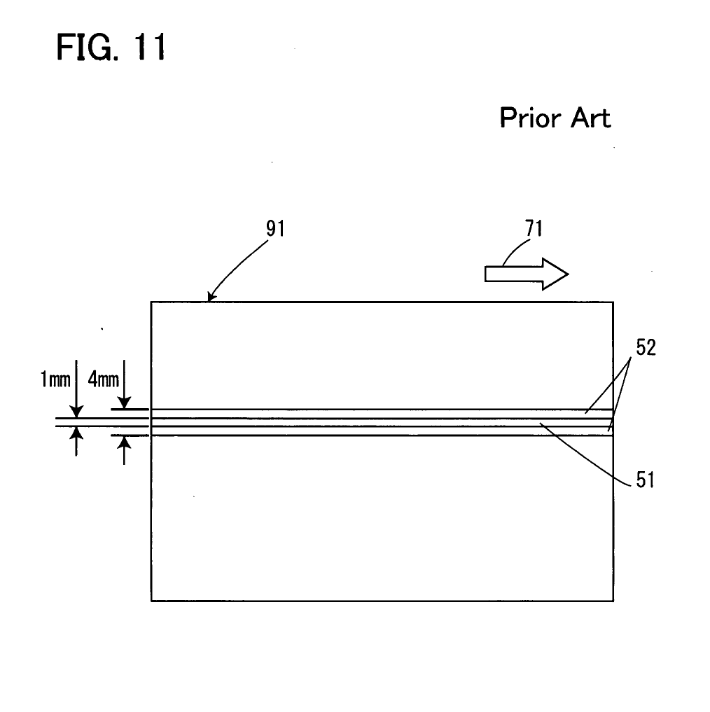

FIG. 12 is a top view illustrating the positions of the board according to the conventional technique and the warpage-preventive rail.

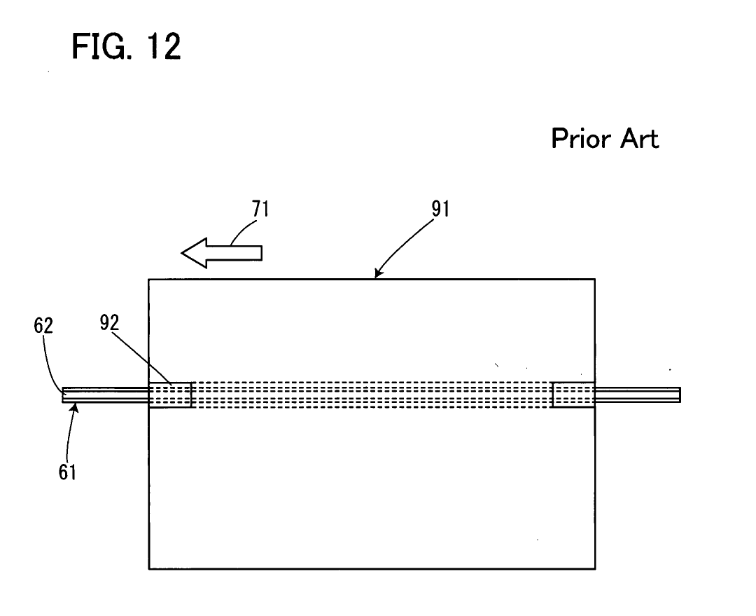

### DESCRIPTION OF THE PREFERRED EMBODIMENTS

Embodiments of the present invention will be described with reference to the accompanying drawings. The following examples are merely specific examples of the invention, and the invention is not limited thereto.

### First Embodiment

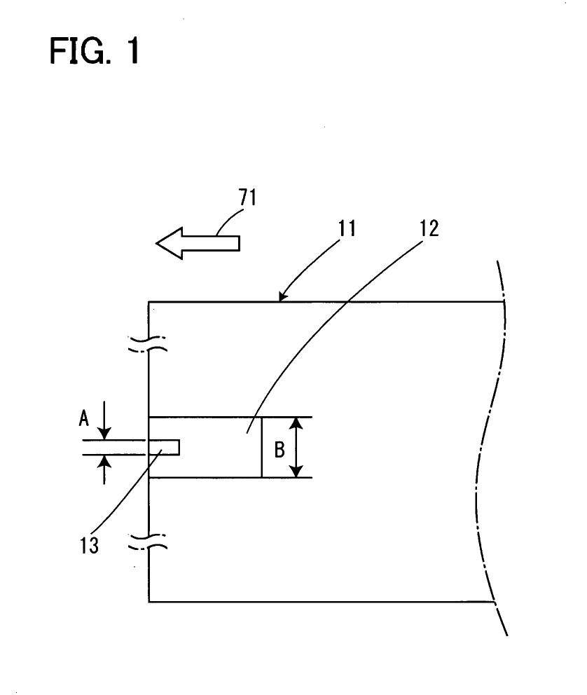

FIG. 1 is an illustration showing a surface (facing upward in flow soldering) opposite to a flow solder surface of a board according to this embodiment. A mark 12 of a width B provided with a slit 13 having a width A in a direction perpendicular to a dip direction indicated by an arrow 71 is silk-screen printed at an end of the surface opposite to the flow solder surface of the board 11.

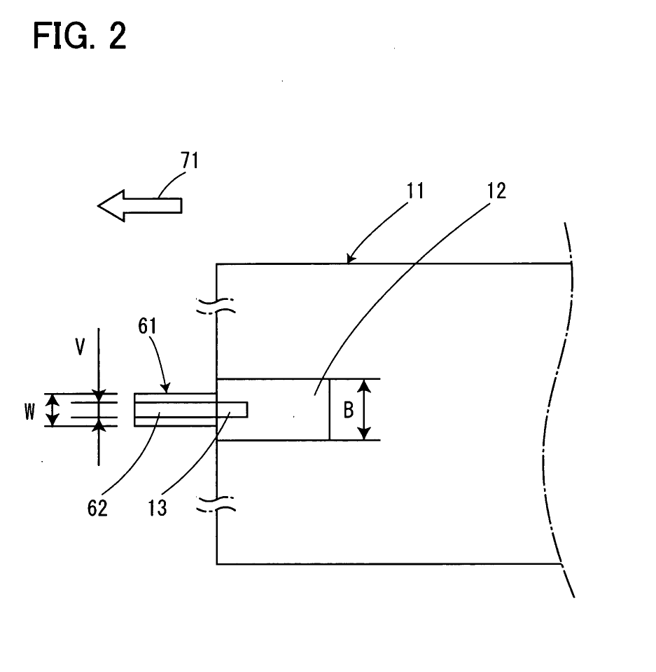

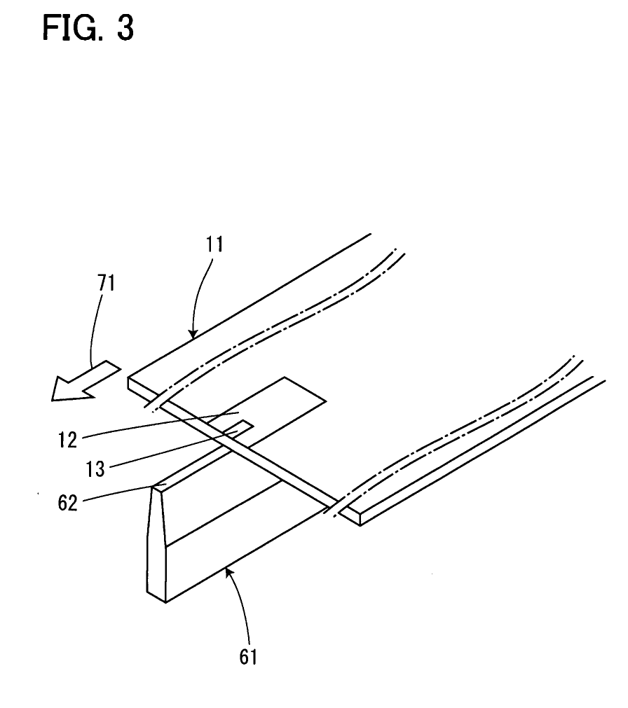

FIGS. 2 and 3 are respectively a top view and a perspective view illustrating the positions of the board 11 shown in FIG. 1 and a warpage-preventive rail 61. The warpage-preventive rail 61 of a width W has an upper surface 62 of a width V facing the board 11. In FIGS. 2 and 3, the same elements as those of FIG. 1 are denoted by the same reference numerals. In flow soldering, the upper surface 62 supports approximately the center portion of the board 11, thereby preventing downward warpage.

The width B of the mark 12 is set to such a value (e.g., 4 mm) that an operator who adjusts the position of the warpage-preventive rail 61 can easily recognize the mark. The slit 13 is formed on the surface opposite to a support band where the upper surface 62 of the warpage-preventive rail 61 supports the board 11, and the width A of the slit 13 is set to a value approximately equal to the width V of the upper surface 62. For example, in the case where the width V of the upper surface 62 is 1 mm, the width A of the slit 13 is set to approximately 1 mm. With such a value, it becomes possible to easily perform positioning of the rail 61 by aligning the upper surface 62 with the slit 13.

As described above, according to this embodiment of the invention, since it is possible to easily recognize the mark and form on the board the slit approximately equal to the width of the warpage-preventive rail, it is possible to provide a positioning method for swiftly and accurately adjusting the position of the warpage-preventive rail and provide a board for swiftly and accurately adjusting the position of the warpage-preventive rail. Further, since it is possible to form the mark by silk-screen printing as well as other board information, it is possible at low cost to provide the positioning method for swiftly and accurately adjusting the position of the warpage-preventive rail and provide the board for swiftly and accurately adjusting the position of the warpage-preventive rail.

Further, this embodiment of the invention does not require a notch to be formed in the board, and therefore is applicable even to such a small board that traces are congested in the vicinity of the end of the board. Furthermore, this embodiment can be achieved on a board produced in the past only by modifying a portion, corresponding to the mark, in a film for silk-screen printing, thus enabling cost reduction.

### Second Embodiment

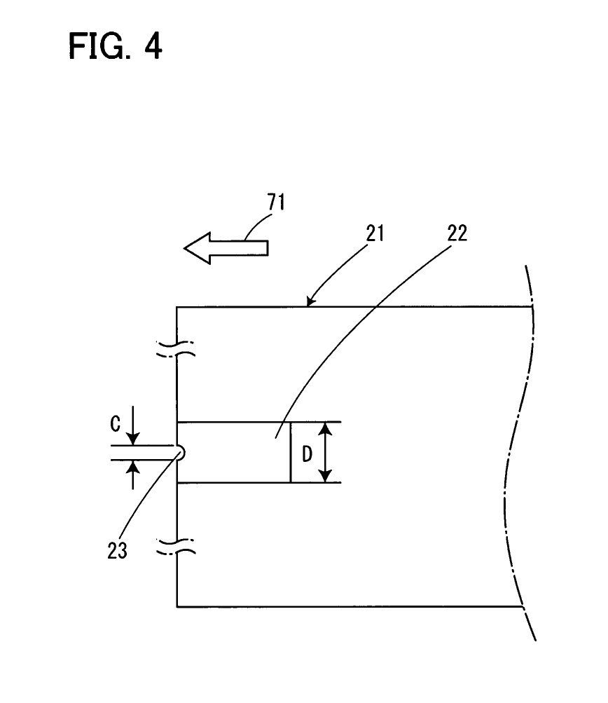

FIG. 4 is an illustration showing a surface (facing upward in flow soldering) opposite to a flow solder surface of a board according to this embodiment. A mark 22 of a width D provided with a notch 23 having a width C in a direction perpendicular to a dip direction indicated by an arrow 71 is silk-screen printed at an end of the surface opposite to the flow solder surface of the board 21.

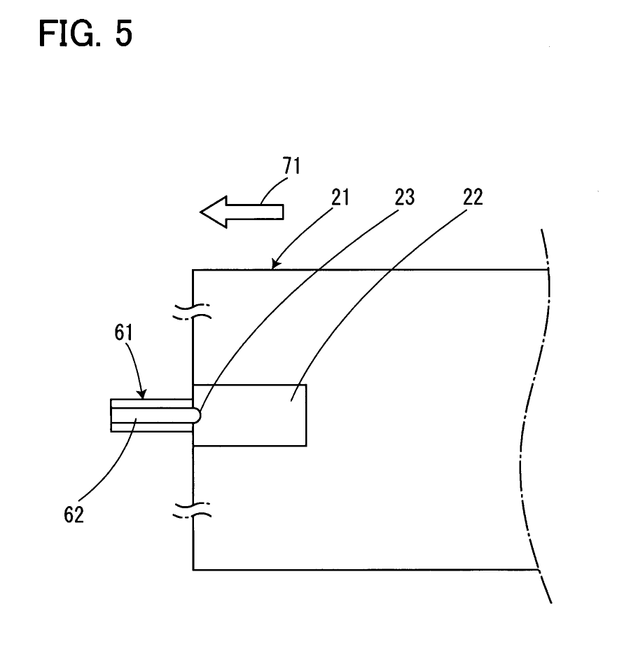

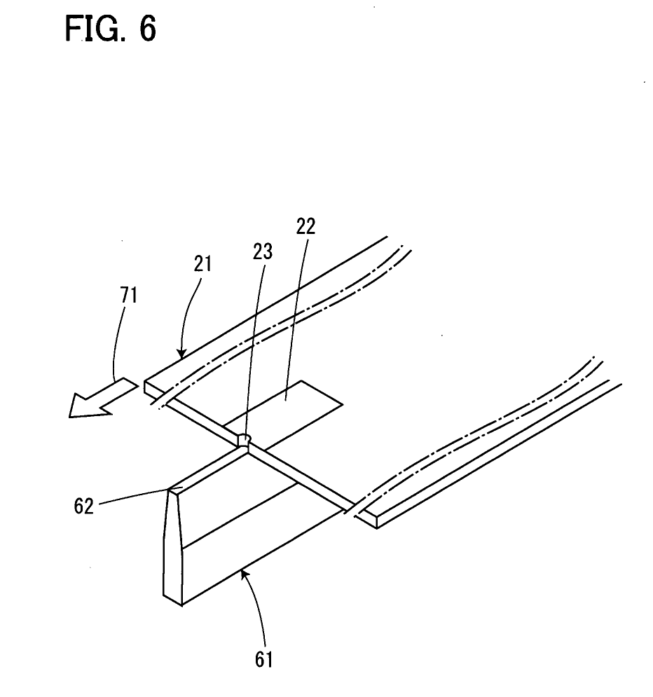

FIGS. 5 and 6 are respectively a top view and a perspective view illustrating the positions of the board 21 shown in FIG. 4 and the warpage-preventive rail 61. In FIGS. 5 and 6, the same elements as those of FIG. 4 are denoted by the same reference numerals. The warpage-preventive rail 61 is the same as that described in the first embodiment. In flow soldering, the upper surface 62 supports approximately the center portion of the board 21, thereby preventing downward warpage.

The width D of the mark 22 is set to such a value (e.g., 4 mm) that an operator who adjusts the position of the warpage-preventive rail 61 can easily recognize the mark. The notch 23 is formed on the surface opposite to the support band where the upper surface 62 of the warpage-preventive rail 61 supports the board 21, and the width C of the notch 23 is set to approximately the width V of the upper surface 62. For example, in the case where the width V of the upper surface 62 is 1 mm, the width C of the notch 23 is set to approximately 1 mm. With such a value, it becomes possible to easily perform positioning of the rail 61 by aligning the upper surface 62 with the notch 23.

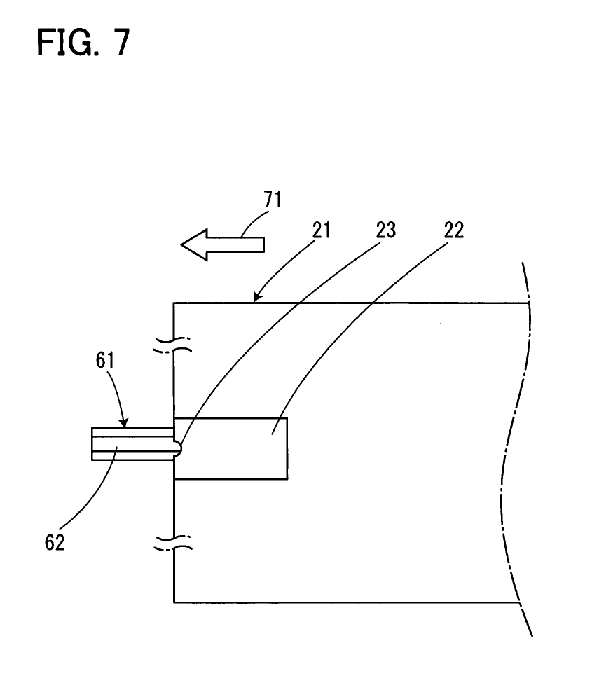

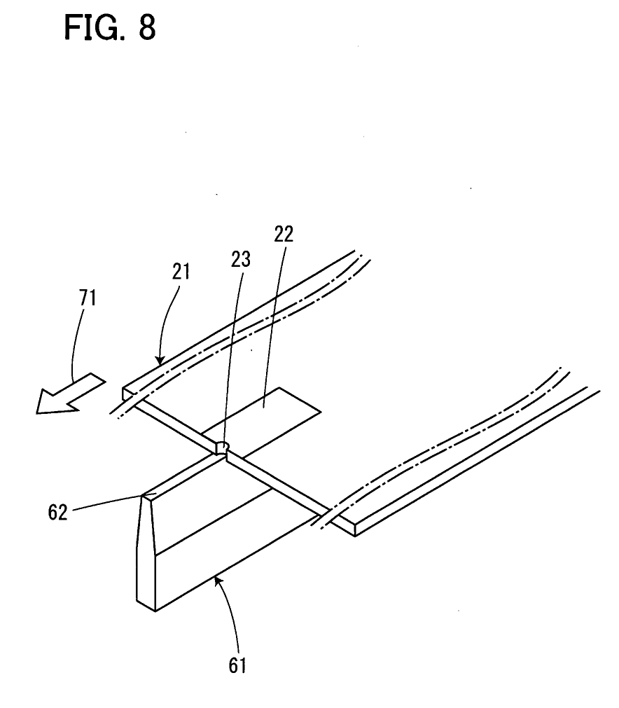

FIGS. 7 and 8 are respectively a top view and a perspective view illustrating the positions of the board 21 and the warpage-preventive rail 61 in the case where the upper surface 62 of the warpage-preventive rail 61 and the notch 23 are misaligned. Depending on a soldering apparatus, there are cases where the operator cannot see the board 21 from directly above in terms of structure when adjusting the position of the warpage-preventive rail 61, but only from diagonally above. Even in such a case, as is clear from FIGS. 7 and 8, since it is possible to recognize the position of the upper surface 62 through the notch 23, the positioning can be easily performed.

As described above, according to this embodiment of the invention, since it is possible to easily recognize the mark and form on the board the notch approximately equal to the width of the warpage-preventive rail, it is possible to provide a positioning method for swiftly and accurately adjusting the position of the warpage-preventive rail and provide a board for swiftly and accurately adjusting the position of the warpage-preventive rail. Further, since it is possible to form the mark by silk-screen printing as well as other board information, it is possible at low cost to provide the positioning method for swiftly and accurately adjusting the position of the warpage-preventive rail and provide the board for swiftly and accurately adjusting the position of the warpage-preventive rail.

Further, this embodiment of the invention is applicable to the case where the board cannot be seen from directly above.

It should be understood by those skilled in the art that various modifications, combinations, sub-combinations and alterations may occur depending on design requirements and other factors insofar as they are within the scope of the appended claims or the equivalents thereof.

The effects of the present invention are as follows.

According to the invention, since it is possible to easily recognize the mark and form on the board the slit or the notch approximately equal to the width of the warpage-preventive rail, it is possible to provide a positioning method for swiftly and accurately adjusting the position of the warpage-preventive rail and provide a board for swiftly and accurately adjusting the position of the warpage-preventive rail. Further, since it is possible to form the mark by silk-screen printing as well as other board information, it is possible at low cost to provide the positioning method for swiftly and accurately adjusting the position of the warpage-preventive rail and provide the board for swiftly and accurately adjusting the position of the warpage-preventive rail.

What is claimed is:

1. A positioning method of a warpage-preventive rail for supporting a board from below to prevent downward warpage of the board when a component is flow-soldered onto the board in a molten solder bath, the positioning method comprising the steps of:
forming a mark provided with a slit having a width approximately equal to a width, perpendicular to a dip direction, of a surface of the warpage-preventive rail facing the board, at an end of a surface opposite to a flow solder surface of the board; and
adjusting a position of the warpage-preventive rail to the slit.

2. A positioning method of a warpage-preventive rail for supporting a board from below to prevent downward warpage of the board when a component is flow-soldered onto the board in a molten solder bath, the positioning method comprising the steps of:
forming a notch having a width approximately equal to a width, perpendicular to a dip direction, of a surface of the warpage-preventive rail facing the board, at an end of a surface opposite to a flow solder surface of the board;
forming a mark around the notch; and
adjusting a position of the warpage-preventive rail to the notch.

3. The positioning method according to claim 1 or 2, wherein the mark is formed by silk-screen printing.

4. A board that is supported from below by a warpage-preventive rail for preventing downward warpage of the board when a component is flow-soldered onto the board in a molten solder bath, the board comprising:
a mark provided with a slit having a width approximately equal to a width, perpendicular to a dip direction, of a surface of the warpage-preventive rail facing the board, at an end of a surface opposite to a flow solder surface of the board.

5. A board that is supported from below by a warpage-preventive rail for preventing downward warpage of the board when a component is flow-soldered onto the board in a molten solder bath, the board comprising:
a notch having a width approximately equal to a width, perpendicular to a dip direction, of a surface of the warpage-preventive rail facing the board, at an end of a surface opposite to a flow solder surface of the board; and
a mark formed around the notch.

6. The board according to claim 4 or 5, wherein the mark is formed by silk-screen printing.
